(19) United States
(12) Patent Application Publication
(10) Pub. No.: US 2015/0187566 A1
(43) Pub. Date: Jul. 2, 2015

(54) HARDMASK COMPOSITION, METHOD OF FORMING PATTERNS USING THE HARDMASK COMPOSITION AND SEMICONDUCTOR INTEGRATED CIRCUIT DEVICE INCLUDING THE PATTERNS

(71) Applicant: SAMSUNG SDI CO., LTD., Yongin-si (KR)

(72) Inventors: Yu-Shin PARK, Suwon-si (KR); Yun-Jun KIM, Suwon-si (KR); Joon-Young MOON, Suwon-si (KR); You-Jung PARK, Suwon-si (KR); Hyun-Ji SONG, Suwon-si (KR); Seung-Wook SHIN, Suwon-si (KR); Yong-Woon YOON, Suwon-si (KR); Chung-Heon LEE, Suwon-si (KR); Yoo-Jeong CHOI, Suwon-si (KR)

(21) Appl. No.: 14/533,200

(22) Filed: Nov. 5, 2014

(30) Foreign Application Priority Data
Dec. 31, 2013 (KR) 10-2013-0169260

(51) Int. Cl. H01L 21/027; H01L 21/308; H01L 21/306; C08L 65/02; H01L 21/02

(52) U.S. Cl. CPC H01L 21/0276; C08L 65/02; H01L 21/02118; H01L 21/02282; H01L 21/30604; H01L 21/3081; H01L 21/3086

(57) ABSTRACT

A hardmask composition includes a polymer including a moiety represented by one of the following Chemical Formulae 1a to 1c, a monomer represented by the following Chemical Formula 2 and a solvent.

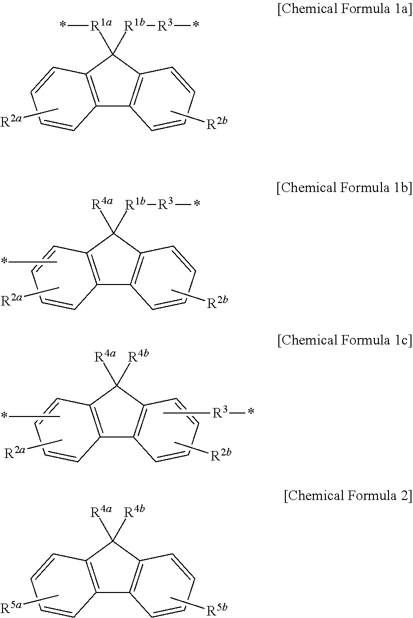

In the above Chemical Formulae 1a, 1b, 1c, and 2,
R^{1a}, R^{1b}, R^{4a}, R^{4b}, R^{2a}, R^{2b}, R^{5a}, R^{5b} and R³ are the same as defined in the specification.

### CROSS-REFERENCE TO RELATED APPLICATION

Korean Patent Application No. 10-2013-0169260 filed on Dec. 31, 2013, in the Korean Intellectual Property Office, and entitled: “Hardmask Composition, Method of Forming Patterns Using the Hardmask Composition and Semiconductor Integrated Circuit Device Including the Patterns,” is incorporated by reference herein in its entirety.

### BACKGROUND

1. Field

A hardmask composition, a method of forming patterns using the same, and a semiconductor integrated circuit device including the patterns are disclosed.

2. Description of the Related Art

Recently, the semiconductor industry has developed techniques for providing ultrafine patterns of several to several tens nanometer size. To provide such ultrafine patterns, effective lithographic techniques are desirable.

### SUMMARY

Embodiments are directed to a hardmask composition including a polymer including a moiety represented by one of the following Chemical Formulae 1a to 1c, a monomer represented by the following Chemical Formula 2, and a solvent.

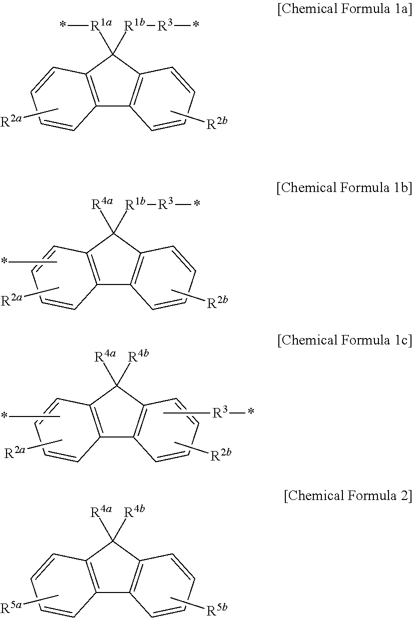

In the above Chemical Formulae 1a, 1b, 1c, and 2,

R^{1a} and R^{1b} are independently linking groups formed by substituting any two hydrogen atoms in one compound selected from the following Group 1,

R^{4a} and R^{4b} are independently substituents formed by substituting any one hydrogen atom in one compound selected from the following Group 1,

R^{2a}, R^{2b}, R^{5a} and R^{5b} are independently selected from hydrogen, a hydroxy group, an amine group, a substituted or unsubstituted C1 to C10 alkyl group, a substituted or unsubstituted C6 to C10 aryl group, a substituted or unsubstituted C1 to C10 allyl group, and a halogen.

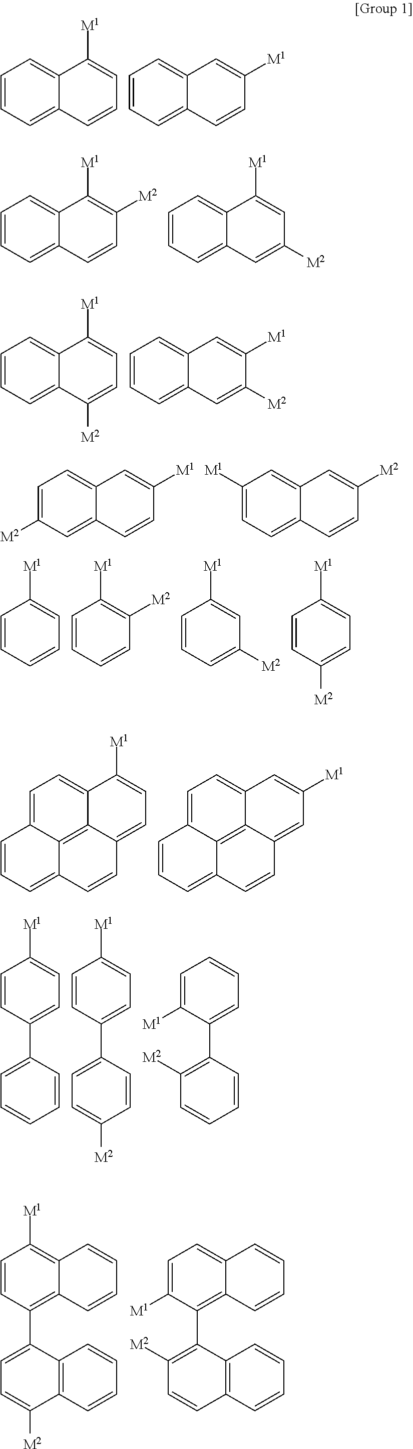

In Group 1, M¹ and M² are independently hydrogen, a hydroxy group, a thionyl group, a thiol group, a cyano group, a substituted or unsubstituted amino group, a halogen, a halogen-containing group, a substituted or unsubstituted C1 to C30 alkoxy group.

R³ is selected from the following Group 2.

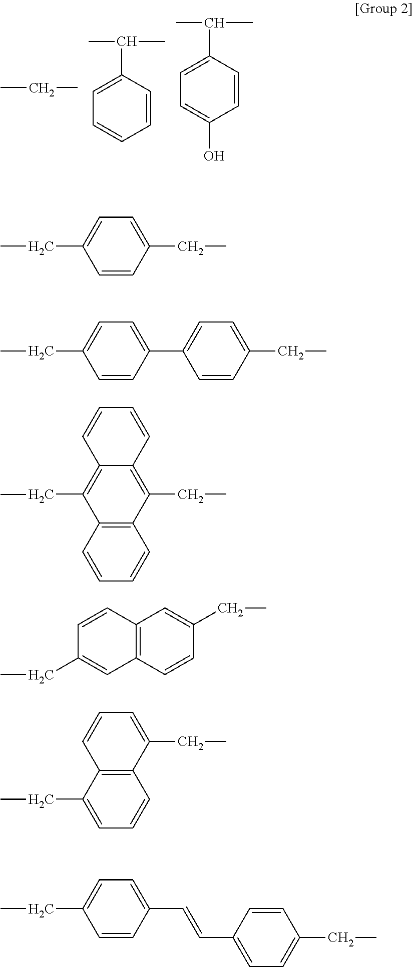

The polymer may further include a moiety represented by the following Chemical Formula 3.

*-R⁶—R⁷-* [Chemical Formula 3]

In the above Chemical Formula 3,

R⁶ is a linking group formed by substituting any two hydrogen atoms in one compound selected from Group 1, and

R⁷ is one selected from Group 2.

The polymer may have a weight average molecular weight of about 1,000 to about 200,000.

A weight ratio of the polymer to the monomer may be about 9:1 to about 1:9.

The polymer and the monomer may be included in an amount of about 5 parts by weight to about 100 parts by weight based on 100 parts by weight of the solvent.

The solvent may include at least one selected from propylene glycol monomethyl ether acetate (PGMEA), propylene glycol monomethylether (PGME), cyclohexanone, and ethyl lactate.

The hardmask composition may further include a cross-linking agent.

For R^{4a} and R^{4b} in Chemical Formula 2, M¹ may be a hydroxy group.

Embodiments are also directed to a method of forming patterns that includes providing a material layer on a substrate, applying the hardmask composition on the material layer to form a hardmask layer, heat-treating the hardmask composition to form a hardmask layer, forming a silicon-containing thin layer on the hardmask layer, forming a photoresist layer on the silicon-containing thin layer, exposing and developing the photoresist layer to form a photoresist pattern, selectively removing the silicon-containing thin layer and the hardmask layer using the photoresist pattern to expose a part of the material layer and etching an exposed part of the material layer.

The hardmask composition may be applied using a spin-on coating method.

Forming the hardmask layer may include heat-treating at about 100° C. to about 500° C.

The method may further include forming a bottom antireflective coating (BARC) on the silicon-containing thin layer.

The silicon-containing thin layer may include silicon oxynitride (SiON), silicon nitride (Si₃N4), or a combination thereof.

According to another embodiment, a semiconductor integrated circuit device including a plurality of pattern formed by the method of forming patterns is provided.

### DETAILED DESCRIPTION

Example embodiments will now be described more fully hereinafter; however, they may be embodied in different forms and should not be construed as limited to the embodiments set forth herein. Rather, these embodiments are provided so that this disclosure will be thorough and complete, and will fully convey exemplary implementations to those skilled in the art.

As used herein, when a definition is not otherwise provided, the term ‘substituted’ may refer to one substituted with a substituent selected from a halogen atom (F, Br, Cl, or I), a hydroxy group, an alkoxy group, a nitro group, a cyano group, an amino group, an azido group, an amidino group, a hydrazino group, a hydrazono group, a carbonyl group, a carbamyl group, a thiol group, an ester group, a carboxyl group or a salt thereof, a sulfonic acid group or a salt thereof, a phosphoric acid group or a salt thereof, a C1 to C20 alkyl group, a C2 to C20 alkenyl group, a C2 to C20 alkynyl group, a C6 to C30 aryl group, a C7 to C30 arylalkyl group, a substituted or unsubstituted C1 to C20 alkylborane group, a substituted or unsubstituted C6 to C30 arylborane group, a C1 to C4 alkoxy group, a C1 to C20 heteroalkyl group, a C3 to C20 heteroarylalkyl group, C3 to C30 cycloalkyl group, a C3 to C15 cycloalkenyl group, a C6 to C15 cycloalkynyl group, a C2 to C30 heterocycloalkyl group, and a combination thereof, instead of a hydrogen atom of a compound.

As used herein, when a definition is not otherwise provided, the term ‘hetero’ refers to one including 1 to 3 heteroatoms selected from B, N, O, S, and P.

Hereinafter, a hardmask composition according to an embodiment is described.

A hardmask composition according to an embodiment may include a polymer including a moiety represented by one of the following Chemical Formulae 1a to 1c, a monomer represented by the following Chemical Formula 2, and a solvent.

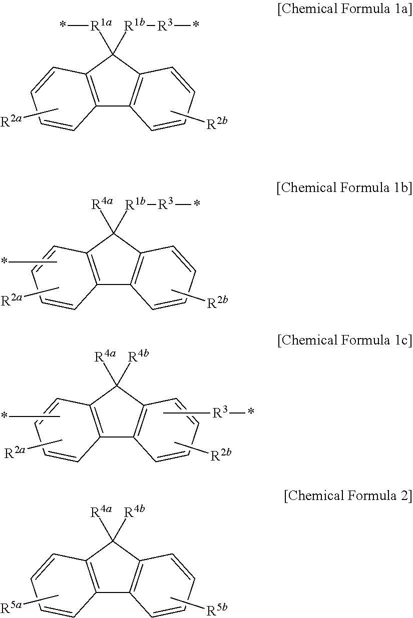

In the above Chemical Formulae 1a, 1b, 1c, and 2,

R^{1a} and R^{1b} are independently linking groups formed by substituting any two hydrogen atoms in one compound selected from the following Group 1,

R^{4a} and R^{4b} are independently substituents formed by substituting any one hydrogen atoms in one compound selected from the following Group 1,

R^{2a}, R^{2b}, R^{5a} and R^{5b} are independently selected from hydrogen (—H), a hydroxy group (—OH), an amine group (—NH₂), a substituted or unsubstituted C1 to C10 alkyl group, a substituted or unsubstituted C6 to C10 aryl group, a substituted or unsubstituted C1 to C10 allyl group, and a halogen.

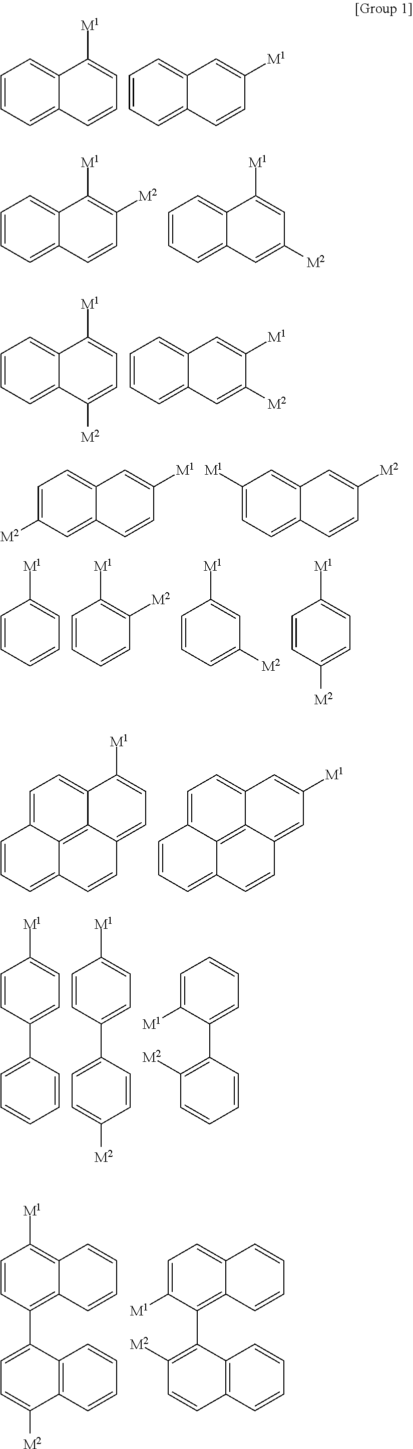

In Group 1, M¹ and M² are independently hydrogen, a hydroxy group, a thionyl group, a thiol group, a cyano group, a substituted or unsubstituted amino group, a halogen, a halogen-containing group, a substituted or unsubstituted C1 to C30 alkoxy group.

In Group 1, each linking position of each ring is not particularly limited.

R³ is selected from the following Group 2.

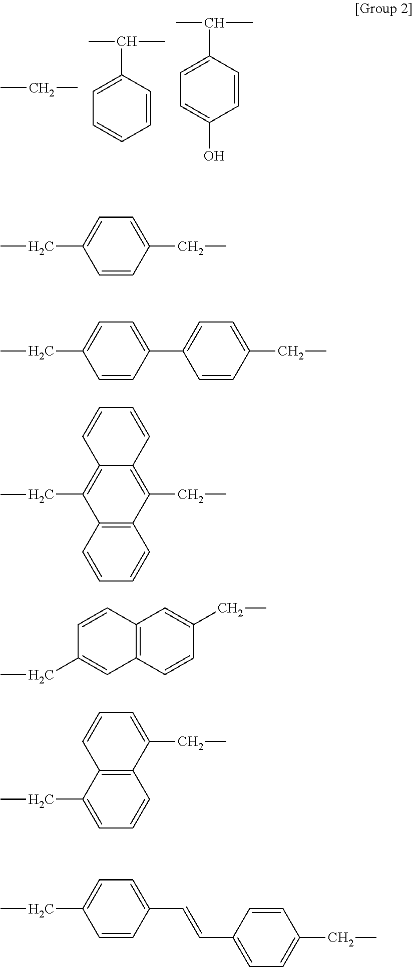

The moiety represented by one of the above Chemical Formulae 1a to 1c has an aromatic ring. A hardmask composition including a polymer having the moiety may provide rigid characteristics.

The hardmask composition may include a compound obtained by blending a polymer including the moiety represented by one of the above Chemical Formulae 1a to 1c and a monomer represented by the above Chemical Formula 2. The hardmask composition may have satisfactory heat resistance and etch resistance and may provide suitable solubility, gap-filling and planarization characteristics.

The moiety represented by one of the above Chemical Formulae 1a to 1c and the monomer represented by the above Chemical Formula 2 all have a fluorene backbone. The hardmask composition therefore includes a composition obtained by blending the polymer and a monomer having a similar structure each other. Accordingly, the composition may decrease a repelling power and sense of a difference between the polymer and the monomer and may help the polymer and the monomer be well dispersed in the composition. The polymer and the monomer may compensate for a drawback of each moiety and may secure excellent gap-fill characteristics and planarization characteristics. In addition, the polymer and the monomer having a similar structure may be blended and thus, may minimize a characteristic change of a blended material due to inherent characteristics of the polymer and the monomer.

In above Chemical Formulae 1a to 1c and 2, R^{2a}, R^{2b}, R^{5a} and R^{5b} indicate a substituent substituted in the fluorene backbone. The position and number of the substituent may be appropriately adjusted to control properties.

As described above, the polymer may include a plurality of the moiety represented by one of the above Chemical Formulae 1a to 1c, the plurality of the moieties may have the same structure or a different structure. For example, the polymer may include moieties represented by the above Chemical Formulae 1a and 1b. For example, the polymer may include two different moieties represented by the above Chemical Formula 1a.

The polymer may further include a moiety represented by the following Chemical Formula 3.

*-R⁶—R⁷-* [Chemical Formula 3]

In the above Chemical Formula 3,

R⁶ is a linking group formed by substituting any two hydrogen atoms in one compound selected from Group 1, and

R⁷ is one selected from Group 2.

When the polymer includes the moiety represented by the above Chemical Formula 3, the moieties represented by one of the above Chemical Formulae 1a to 1c and the above Chemical Formula 3 may be provided in a suitable arrangement order and weight ratio.

For example, the moieties represented by one of the above Chemical Formulae 1a to 1c and the above Chemical Formula 3 in the polymer may be used in an appropriate mole ratio within a desired weight average molecular weight range of the polymer. For example, the polymer may have a weight average molecular weight of about 1,000 to about 200,000.

The polymer may include a plurality of the moiety represented by the above Chemical Formula 3, and the moieties may have the same structure or a different structure.

The polymer and the monomer may be used, for example, in a weight ratio of about 9:1 to about 1:9 and specifically, about 7:3 to about 3:7, as examples.

The solvent in the hardmask composition may be a suitable solvent having sufficient dissolubility or dispersion for the polymer and the monomer. The solvent may be, for example at least one selected from propylene glycol, propylene glycol diacetate, methoxy propanediol, diethylene glycol, diethylene glycol butyl ether, tri(ethylene glycol)monomethylether, propylene glycol monomethylether, propylene glycol monomethylether acetate, cyclohexanone, ethyl lactate, gamma-butyrolactone, methyl pyrrolidone, and acetylacetone.

The polymer and monomer may be included in an amount of about 5 to about 100 parts by weight based on 100 parts by weight of the solvent. When polymer and the monomer are included within the above range, a desired thickness of a coated thin film may be obtained.

The hardmask composition may further include a surfactant. The surfactant may include, for example, an alkylbenzene sulfonate salt, an alkyl pyridinium salt, polyethylene glycol, or a quaternary ammonium salt.

The surfactant may be included in an amount of about 0.001 to about 3 parts by weight based on 100 parts by weight of the hardmask composition. Within this amount range, the solubility may be secured without changing the optical properties of the hardmask composition.

The hardmask composition may further include a cross-linking agent.

The cross-linking agent may include at least one selected from an amino resin, a glycoluril compound, bis-epoxy compound, a melamine compound, and a melamine derivative.

The cross-linking agent may be included in an amount of about 0.001 parts by weight to about 3 parts by weight based on 100 parts by weight of the hardmask composition.

Hereafter, a method for forming patterns by using the hardmask composition is described.

A method of forming patterns according to an embodiment includes providing a material layer on a substrate, applying the hardmask composition including the polymer, monomer and solvent on the material layer, heat-treating the hardmask composition to form a hardmask layer, forming a silicon-containing thin layer on the hardmask layer, forming a photoresist layer on the silicon-containing thin layer, exposing and developing the photoresist layer to form a photoresist pattern, selectively removing the silicon-containing thin layer and the hardmask layer using the photoresist pattern to expose a part of the material layer and etching an exposed part of the material layer.

The substrate may be, for example, a silicon wafer, a glass substrate, or a polymer substrate.

The material layer may be a material to be finally patterned, for example a metal layer such as an aluminum layer or a copper layer, a semiconductor layer such as a silicon layer, or an insulation layer such as a silicon oxide layer or a silicon nitride layer. The material layer may be formed through a method such as chemical vapor deposition (CVD).

The hardmask composition may be applied in a form of a solution by spin-on coating. A thickness of the hardmask composition may be, for example about 100 Å to about 10,000 Å.

Heat-treating the hardmask composition may be performed, for example at about 100 to about 500° C. for about 10 seconds to 10 minutes. During heat-treating, the compounds may undergo a self cross-linking and/or mutual cross-linking reaction.

The silicon-containing thin layer may be made of, for example silicon nitride, silicon oxide, or silicon oxynitride (SiON).

The method may further include forming a bottom antireflective coating (BARC) on the silicon-containing thin layer. For example, a silicon oxynitride-containing thin layer may be formed on the hardmask layer, then a bottom antireflective coating may be formed, and subsequently, a photoresist layer may be formed on the bottom antireflective coating.

Exposure of the photoresist layer may be performed using, for example ArF, KrF, or EUV. After exposure, heat treatment may be performed at about 100° C. to about 500° C.

The etching process of the exposed part of the material layer may be performed through a dry etching process using an etching gas. The etching gas may be, for example CHF₃, CF₄, Cl₂, BCl₃, or a mixed gas thereof, without limitation.

The etched material layer may be formed as a plurality of patterns. The plurality of patterns may be a metal pattern, a semiconductor pattern, an insulation pattern, or the like. For example, the plurality of patterns may be diverse patterns of a semiconductor integrated circuit device.

Patterns included in a semiconductor integrated circuit device may be, for example a metal line, a semiconductor pattern, an insulation layer including a contact hole, a bias hole, a damascene trench, or the like.

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

### Synthesis of Monomer and Polymer

### Polymerization Example 1

20 g (0.044 mol) of 6,6′-(9H-fluoren-9,9-diyl)bis(naphthalen-2-ol) and 7.4 g (0.044 mol) of 1,4-bis(methoxymethyl)benzene were sequentially put in a flask and dissolved in 43 g of propylene glycol monomethyl ether acetate (PGMEA). Then, 0.12 g (0.0008 mol) of diethyl sulfate was added thereto, and the mixture was agitated at 90 to 120° C. for 10 to 15 hours. The reaction was terminated when a specimen taken from the reactant every hour had a weight average molecular weight ranging from 3,200 to 4,500.

When the reaction was terminated, the resultant was cooled down to room temperature and allowed to stand. After removing a supernatant therefrom, a precipitate remaining therein was dissolved in 80 g of propylene glycol monomethyl ether acetate (PGMEA), the solution was agitated by using 40 g of hexane, 40 g of methanol and 40 g of distilled water, and the resultant was allowed to stand (first process). The obtained supernatant was removed again, a precipitate remaining therein was dissolved in 40 g of propylene glycol monomethyl ether acetate (PGMEA), the solution was added to 40 g of distilled water and 400 g of methanol, and the mixture was strongly agitated and then, allowed to stand (second process). The first and second processes were regarded as one refinement process, and this refinement process was repeated three times. The refined polymer was dissolved in 80 g of propylene glycol monomethyl ether acetate (PGMEA), and methanol and distilled water remaining in the solution was removed under a reduced pressure, obtaining a compound represented by the following Chemical Formula 4.

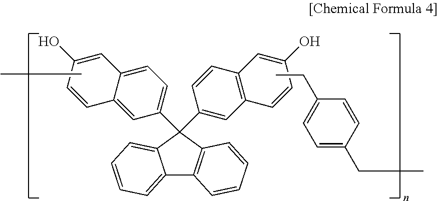

### Polymerization Example 2

20 g (0.044 mol) of 6,6′-(9H-fluoren-9,9-diyl)bis(naphthalen-2-ol) and 1 g (0.033 mol) of paraformaldehyde were sequentially put in a flask and dissolved in 43 g of propylene glycol monomethyl ether acetate (PGMEA). Then, 0.12 g (0.0006 mol) of p-toluene sulfonic acid (PTSA) was added thereto, and the mixture was agitated at 90 to 120° C. for about 5 to 10 hours. The reaction was terminated, when a specimen taken from the reactant every hour had a weight average molecular weight of 3,000 to 4,200.

When the reaction was terminated, the resultant was cooled down to room temperature and added to 40 g of distilled water and 400 g of methanol, and the mixture was strongly agitated and then, allowed to stand. After removing a supernatant therefrom, a precipitate remaining therein was dissolved in 80 g of propylene glycol monomethyl ether acetate (PGMEA), the solution was added to 40 g of hexane, 40 g of methanol and 40 g of distilled water, and the mixture was strongly agitated and then, allowed to stand (first process). A supernatant therefrom was removed again, and a precipitate remaining therein was dissolved in 40 g of propylene glycol monomethyl ether acetate (PGMEA) (second process). The first and second processes were regarded as one refinement process. The refinement process was repeated three times in total. The refined polymer was dissolved in 80 g of propylene glycol monomethyl ether acetate (PGMEA), and methanol and distilled water in the solution was removed under a reduced pressure, obtaining a compound represented by the following Chemical Formula 5. [Chemical Formula 5]

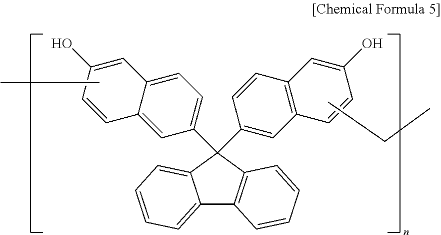

### Polymerization Example 3

20 g (0.057 mol) of 9,9-bis(4-hydroxyphenyl)fluorene and 9.6 g (0.057 mol) of 1,4-bis(methoxymethyl)benzene were sequentially put in a flask and dissolved in 51 g of propylene glycol monomethyl ether acetate (PGMEA). Then, 0.15 g (0.001 mol) of diethyl sulfite was added thereto, and the mixture was agitated at 90 to 120° C. for 5 to 12 hours. The reaction was terminated when a specimen taken from the reactant every hour had a weight average molecular weight of 3,500 to 4,200.

When the reaction was terminated, the resultant was cooled down to room temperature and added to 40 g of distilled water and 400 g of methanol. The mixture was strongly agitated and then, allowed to stand. After removing a supernatant therefrom, a precipitate remaining therein was dissolved in 80 g of propylene glycol monomethyl ether acetate (PGMEA), the solution was added to 40 g of methanol and 40 g of distilled water, and the mixture was strongly agitated and then, allowed to stand (first process). A supernatant obtained therefrom was removed, and a precipitate remaining therein was dissolved in 40 g of propylene glycol monomethyl ether acetate (PGMEA) (second process). The first and second processes were regarded as one refinement process. The refinement process was repeated three times in total. The refined polymer was dissolved in 80 g of propylene glycol monomethyl ether acetate (PGMEA), and methanol and distilled water remaining in the solution were removed under a reduced pressure, obtaining a compound represented by Chemical Formula 6.

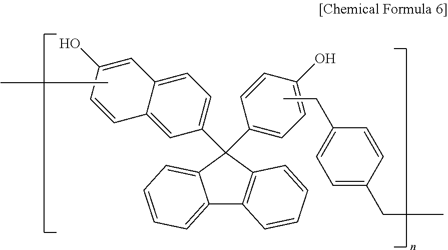

### Comparative Synthesis Example 1

### First Step

### Introduction Reaction of Substituent (Friedel-Craft Acylation)

1.4-cyclohexanedicarbonyl dichloride (28.0 g, 0.1345 mol), methoxypyrene (62.4 g, 0.269 mol) and 1,2-dichloroethane (496 g) were put in a flask to prepare a solution. Then, aluminum chloride (17.9 g, 0.1345 mol) was slowly added to the solution, and the mixture was agitated at room temperature for 12 hours. When the reaction was terminated, methanol was added thereto, and a precipitate formed therein was filtered and dried.

### Second Step

### Demethylation Reaction

The compound (6.00 g, 0.01001 mol), 1-dodecanethiol (10.13 g, 0.05005 mol), potassium hydroxide (3.37 g, 0.06006 mol) and N,N-dimethylformamide (30.3 g) were put in a flask and agitated at 120° C. for 8 hours. The reaction mixture was cooled down and neutralized with a 5% hydrochloric acid solution to about pH 6-7, and a precipitate formed therein was filtered and dried.

### Third Step

### Reduction Reaction

The demethylated compound (4.00 g, 0.00699 mol) and tetrahydrofuran (28.5 g) were put in a flask, preparing a solution. Then, a sodium borohydride (5.29 g, 0.1398 mol) aqueous solution was slowly added to the solution, and the mixture was agitated for 24 hours at room temperature. When the reaction was terminated, the resultant was neutralized with a 5% hydrochloric acid solution about pH 7 and then, extracted with ethylacetate. An extract obtained therefrom was dried, obtaining a compound represented by Chemical Formula 7.

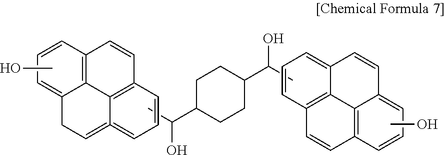

### Preparation of Hardmask Composition

### Example 1

The polymer according to Polymerization Example 1 and 6,6′-(9H-fluoren-9,9-diyl)bis(naphthalen-2-ol) (FBN) in a weight ratio of 7:3 were dissolved in a mixed solvent obtained by mixing propylene glycol monomethyl ether acetate (PGMEA) and cyclohexanone in a ratio of 7:3 (v/v). Subsequently, the solution was filtered, preparing a hardmask composition. The weight of the polymer and the FBN was adjusted based on the entire weight of the hardmask composition depending on a desired thickness.

### Example 2

A hardmask composition was prepared according to the same method as Example 1 except for using the polymer according to Polymerization Example 2.

### Example 3

A hardmask composition was prepared according to the same method as Example 1 except for using the polymer according to Polymerization Example 3.

### Comparative Example 1

The polymer according to Polymerization Example 1 was dissolved in a mixed solvent prepared by mixing propylene glycol monomethyl ether acetate (PGMEA) and cyclohexanone in a ratio of 7:3 (v/v). Subsequently, the solution was filtered, preparing a hardmask composition. The amount of the polymer was adjusted depending on a desired thickness.

### Comparative Example 2

A hardmask composition was prepared according to the same method as Example 1 except for using the compound according to Comparative Synthesis Example 1 instead of the 6,6′-(9H-fluoren-9,9-diyl)bis(naphthalen-2-ol) (FBN).

Evaluation

Evaluation 1: Gap-fill and Planarization Characteristics

The hardmask compositions according to Examples 1 to 3 and Comparative Examples 1 and 2 were respectively spin-coated to be about 2200 Å thick on a patterned silicon wafer. Subsequently, the coated silicon wafer was heat-treated at 400° C. on a hot plate for 120 seconds, and a field emission scanning electronic microscope (FE-SEM) was used to examine gap-fill characteristics and planarization characteristics.

The gap-fill characteristics were evaluated by observing whether the cross-section of the pattern had a void or not. The planarization characteristics were digitized according to the following Calculation Equation 1. In Calculation Equation 1, a smaller difference between h1 and h2 indicates better planarization characteristics.

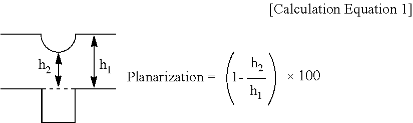

The results are provided in Table 1.

TABLE 1

| | Planarization | Gap-fill |
|---|---|---|
| | characteristics | characteristics |
| Example 1 | 17.8% | No void |
| Example 2 | 21.7% | No void |
| Example 3 | 19.6% | No void |
| Comparative Example 1 | 26.4% | No void |
| Comparative Example 2 | 34% | No void |

Referring to Table 1, the hardmask compositions according to Examples 1 to 3 showed excellent planarization characteristics and also, no void and thus, excellent gap-fill characteristics compared with the hardmask compositions according to Comparative Examples 1 and 2.

Evaluation 2: Heat Resistance

The hardmask compositions (a compound content: 10.0 wt %) according to Examples 1 to 3 and Comparative Example 2 were respectively spin-on coated to form thin films. Subsequently, each thin film was baked at 240° C. on a hot plate for 1 minute, and its thickness was measured. Then, the film was baked at 400° C. for 2 minutes again, and its thickness was measured again. The two thickness measurements were used to calculate a thickness decrease rate according to Calculation Equation 2 and digitize relative heat resistance of the hardmask thin film.

(thickness of a thin film after baking at 240° C.−thickness of a thin film after baking at 400° C.)/thickness of a thin film after baking at 240° C.×100(%) [Calculation Equation 2]

The results are provided in Table 2.

TABLE 2

| | Decrease ratio of thin |
|---|---|
| | film thickness (%) |
| Example 1 | 14.95 |
| Example 2 | 24.6 |
| Example 3 | 28.4 |
| Comparative Example 2 | 31.00 |

Referring to Table 2, the thin films formed of the hardmask compositions according to Examples 1 to 3 showed a lower thickness decrease ratio than the hardmask composition according to Comparative Example 2. Accordingly, the hardmask compositions according to Examples 1 to 3 showed higher heat resistance than the hardmask composition according to Comparative Example 2.

By way of summation and review, a general lithographic technique includes providing a material layer on a semiconductor substrate, coating a photoresist layer thereon, exposing and developing the same to provide a photoresist pattern, and etching the material layer using the photoresist pattern as a mask. However, according to the small size of the pattern to be formed, it may be difficult to provide a fine pattern having an excellent profile by only above-mentioned typical lithographic technique. Accordingly, a layer, called a hardmask layer, may be formed between the material layer and the photoresist layer to provide a fine pattern. The hardmask layer plays a role of an intermediate layer for transferring the fine pattern of photoresist to the material layer through the selective etching process. It is desirable for such a hardmask layer to have characteristics such as heat resistance and etch resistance, or the like in order to tolerate multiple etching processes.

It has been recently suggested to form a hardmask layer by a spin-on coating method instead of by chemical vapor deposition. The spin-on coating method is easy to perform and may also improve gap-fill characteristics and planarization characteristics. The spin-on coating method may use a hardmask composition having dissolubility for a solvent. However, the above-described property of dissolubility may be incompatible with the characteristics desirable for a hardmask layer. Accordingly, a hardmask composition having both properties suitable for a hardmask composition and dissolubility desirable for using a spin-on coating is desirable.

Embodiments advance the art by providing a hardmask composition that satisfies heat resistance and etch resistance while ensuring dissolubility for a solvent, gap-fill characteristics, and planarization characteristics. According to embodiments, characteristics such as heat resistance, etch resistance, planarization characteristics, and gap-fill characteristics required for a hardmask layer may be improved.

Embodiments further provide a method of forming patterns using the hardmask composition and a semiconductor integrated circuit device including patterns formed by the method.

Example embodiments have been disclosed herein, and although specific terms are employed, they are used and are to be interpreted in a generic and descriptive sense only and not for purpose of limitation. Accordingly, it will be understood by those of skill in the art that various changes in form and details may be made without departing from the spirit and scope thereof as set forth in the following claims.

What is claimed is:

1. A hardmask composition, comprising
a polymer including a moiety represented by one of the following Chemical Formulae 1a to 1c,
a monomer represented by the following Chemical Formula 2, and
a solvent: 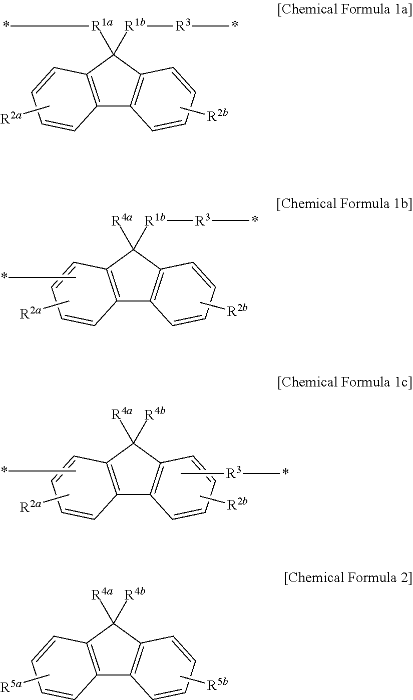
wherein, in the above Chemical Formulae 1a, 1b, 1c, and 2,
R^{1a} and R^{1b} are independently linking groups formed by substituting any two hydrogen atoms in one compound selected from the following Group 1,
R^{4a} and R^{4b} are independently substituents formed by substituting any one hydrogen atom in one compound selected from the following Group 1,
R^{2a}, R^{2b}, R^{5a} and R^{5b} are independently selected from hydrogen, a hydroxy group, an amine group, a substituted or unsubstituted C1 to C10 alkyl group, a substituted or unsubstituted C6 to C10 aryl group, a substituted or unsubstituted C1 to C10 allyl group, and a halogen: 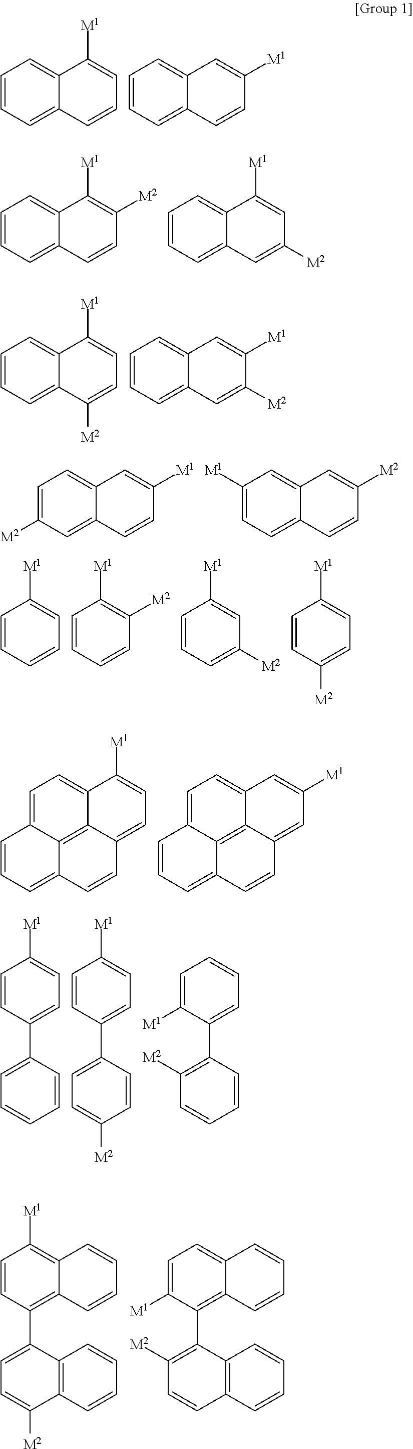
wherein, in Group 1,
M¹ and M² are independently hydrogen, a hydroxy group, a thionyl group, a thiol group, a cyano group, a substituted or unsubstituted amino group, a halogen, a halogen-containing group, a substituted or unsubstituted C1 to C30 alkoxy group, and
R³ is selected from the following Group 2:

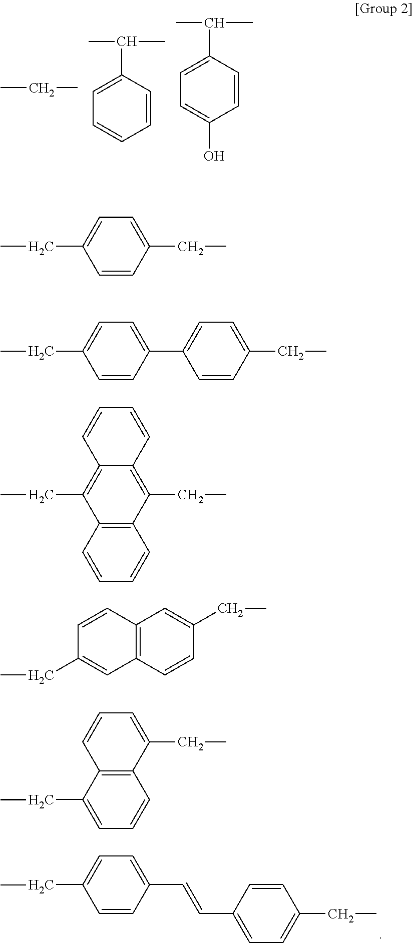

2. The resist underlayer composition as claimed in claim 1, wherein the polymer further includes a moiety represented by the following Chemical Formula 3:
*-R⁶—R⁷-* [Chemical Formula 3]
wherein, in the above Chemical Formula 3,
R⁶ is a linking group formed by substituting any two hydrogen atoms in one compound selected from Group 1,
R⁷ is one selected from Group 2.

3. The hardmask composition as claimed in claim 1, wherein the polymer has a weight average molecular weight of about 1,000 to about 200,000.

4. The hardmask composition as claimed in claim 1, wherein a weight ratio of the polymer to the monomer is about 9:1 to about 1:9.

5. The hardmask composition as claimed in claim 1, wherein the polymer and the monomer are included in an amount of about 5 parts by weight to about 100 parts by weight based on 100 parts by weight of the solvent.

6. The hardmask composition as claimed in claim 1, wherein the solvent includes at least one selected from propylene glycol monomethyl ether acetate (PGMEA), propylene glycol monomethylether (PGME), cyclohexanone, and ethyl lactate.

7. The hardmask composition as claimed in claim 1, wherein the hardmask composition further comprises a cross-linking agent.

8. The hardmask composition as claimed in claim 1, wherein for R^{4a} and R^{4b} in Chemical Formula 2, M¹ is a hydroxy group.

9. A method of forming patterns, the method comprising
providing a material layer on a substrate,
applying the hardmask composition as claimed in claim 1 on the material layer,
heat-treating the hardmask composition to form a hardmask layer,
forming a silicon-containing thin layer on the hardmask layer,
forming a photoresist layer on the silicon-containing thin layer,
exposing and developing the photoresist layer to form a photoresist pattern,
selectively removing the silicon-containing thin layer and the hardmask layer using the photoresist pattern to expose a part of the material layer, and
etching an exposed part of the material layer.

10. The method as claimed in claim 9, wherein the hardmask composition is applied using a spin-on coating method.

11. The method as claimed in claim 9, wherein forming the hardmask layer includes heat-treating at about 100° C. to about 500° C.

12. The method as claimed in claim 9, further comprising forming a bottom antireflective coating (BARC) on the silicon-containing thin layer.

13. The method as claimed in claim 8, wherein the silicon-containing thin layer includes silicon oxynitride (SiON), silicon nitride (Si₃N4), or a combination thereof.

14. A semiconductor integrated circuit device, comprising a plurality of patterns formed by the method of forming patterns as claimed in claim 9.
